(19) United States
(12) Patent Application Publication
(10) Pub. No.: US 2014/0042320 A1
(43) Pub. Date: Feb. 13, 2014

(54) EMI FILTERING DETECTOR AND METHOD FOR SAME

(71) Applicants: Gerhard Knaup, Einhausen (DE); Fred Plotz, Tanunsstein (DE)

(72) Inventors: Gerhard Knaup, Einhausen (DE); Fred Plotz, Tanunsstein (DE)

(73) Assignee: EXCELITAS TECHNOLOGIES SINGAPORE PTE. LTD., SOLARIS (SG)

(21) Appl. No.: 13/569,898

(22) Filed: Aug. 8, 2012

(51) Int. Cl. G01J 5/10; H05K 3/00

(52) U.S. Cl. 250/338.3; 29/846

(57) ABSTRACT

A circuit for detecting electromagnetic radiation includes a pyroelectric sensor element connected to convert electromagnetic radiation into an electric signal. An n-channel junction field effect transistor is connected to receive the electric signal. A printed circuit board includes at least one low inductance low resistance area to provide a ground path for all alternating current components. A first capacitor is connected between the FET source terminal and a second capacitor is connected between the FET drain terminal and ground. A gate resistor is connected in parallel with the sensor element or a resistor is included in the sensor elements.

### FIELD OF THE INVENTION

The present invention relates to electromagnetic detectors, and more particularly, is related to pyroelectric detectors with EMI filtering.

### BACKGROUND OF THE INVENTION

Detectors are known for detecting electromagnetic radiation such as heat radiation or infrared radiation. One application for such detectors is a motion detector. Motion detectors detect, for example, persons, by detecting the heat radiation emitted by the persons. After detection of a person, the motion detector emits a signal which can be further processed as desired. For example, a door opener may be actuated, a light may be switched on, or an alarm may be triggered upon the detection of a person within the sensing field of the motion detector. The target signal for these further processes, for example, infrared radiation from the person being detected, generally changes at a low frequency. An important region for a signal detection is around 1 Hz. The frequency of the signal is at least partially determined from the speed with which the infrared source, the person, passes by the sensor elements.

A first prior art sensing circuit is shown in FIG. 1 as an example of one design for a detector. A sensor which operates capacitively serves as the sensor element. The sensor element of the illustrated exemplary circuit is a pyroelectric cell 2. The sensor cell produces charges corresponding to a change in the intensity of the infrared radiation striking it, and stores these charges capacitively. One terminal of the sensor element is connected to a fixed reference potential, such as ground. The other terminal of the sensor 2 supplies a voltage as an output signal. Since the output has an extremely high impedance, an impedance converter is connected to the output so that an evaluation circuit which may be connected for utilizing the sensor output sees a sufficiently low equivalent resistance for the circuit 1. A high impedance resistor 4 is typically connected in parallel to the sensor element 2 or a high impedance resistor is included in the sensor elements. The resistor 4 ensures that charges accumulated in the capacitive sensor 2 are eventually discharged so that the charge disappears slowly after the heat source which triggered the charge has disappeared. The impedance converter in the standard circuit is a field-effect transistor (FET) 3. One terminal of the FET 3 is connected to a supply voltage U_{B} while the other terminal of the field-effect transistor 3 supplies the output signal U_{A} for further processing. In a circuit using an n-channel junction gate FET 3, the sensor element 2 is connected between ground and the gate of the FET, the drain is connected to the supply voltage U_{B} and the source is connected to supply the output signal U_{A}.

The sensor elements 2 have an extremely high characteristic impedance which is on the order of magnitude of 100 G ohms. As a result of this, the output signal of the sensor elements 2 induced by the incident infrared radiation is very weak, so the entire circuit is rendered unusually susceptible to electrical disturbances. Radio frequency electrical disturbances, including electromagnetic interference (EMI) cause problems in the detector circuit. For the present invention, radio frequency refers to frequencies in the MHz and GHz range. Radio frequencies which are coupled in via the supply lines are particularly disturbing to the circuit operation. However, directly received radio frequency disturbances also play a part, such as those from radio telephone devices or the like. The radio frequency disturbances may lead to malfunctioning of the circuit 1, for example, false detection events, or masking of signals that should trigger detection.

In attempts to reduce such false detection events, a source-ground capacitor 5 has been used in the past, which is connected between the signal output 7 and ground. The source-ground capacitor 5 functions as a low pass filter which short circuits the high output frequencies so that these high frequencies are attenuated at the output of the circuit.

Other modifications to the circuit design further attempt to improve EMI filtering, for example as shown in FIG. 2, are disclosed by U.S. Pat. No. 6,013,914, which is incorporated by reference herein in its entirety. An impedance 6 which is either a purely ohmic impedance or an ohmic and inductive impedance or a purely inductive impedance is connected between the second power terminal, the drain, for example, of the FET 3 and the supply voltage U_{B}. The voltage produced at the gate of the FET 3 across the high impedance resistor 4 by the sensor elements 2 is transmitted to the output U_{A}.

FIG. 3 shows the top and back of a prior art printed circuit board (PCB) for a standard pyroelectric detector. The circuit components are generally mounted to the PCB top 300, while traces connecting the housing (not shown) to ground are formed on the PCB back 301. An FET 3 (FIG. 2) is mounted on the FET gate pad 310, which also serves as the electrical connector to the FET 3 (FIG. 2) gate. One or more pyroelectric elements 2 (FIG. 2) are connected to sensor connector pads 312.

An FET source pad 320 is the electrical connector to the FET 3 (FIG. 2) source. A source-capacitor trace 330 connects the FET 3 (FIG. 2) source to a source-ground capacitor source pad 322. A source-ground capacitor 5 (FIG. 2) is connected across the source-ground capacitor source pad 322 and a source-ground capacitor ground pad 324. The source-ground capacitor ground pad 324 is electrically connected to a source back ground pad 360 by a source-ground via 326. An FET drain pad 340 is the electrical connector to the FET 3 (FIG. 2) drain via a resistor 6. A front ground pad 342 is electrically connected to a back-side ground pad 370 by a drain-ground via 346. A ground housing pad 380 is used to ground the PCB to the detector housing (not shown).

An increasing number of devices operating in the higher end of the frequency range detectable by infrared motion sensors are being commonly deployed. Such devices include, for example, cordless telephones and baby monitors operating at 900 MHz to 1.9 GHz, Bluetooth devices operating from 2.4 to 2.4835 GHz, radio controlled model aircraft and cars in the 2.4 GHz range, car alarms, microwave ovens, IEEE 802.11 WiFi networks and devices, video monitoring systems, ZigBee/IEEE 802.15.4, and other devices.

The increasing prevalence of devices producing EMI in higher frequency ranges has led to greater demand for more robust radiation detectors with less susceptibility to malfunctions due to the presence of EMI. In particular, there is a need to replace existing radiation detectors with more robust detectors having a similar form factor to previous radiation detectors, and for the improved radiation detectors to provide similar detection capabilities but with improved performance in the presence of EMI without significant increases in cost. Therefore, there is a need in the industry to address at least some of the aforementioned shortcomings.

### SUMMARY OF THE INVENTION

It is an objective of the present invention to provide a detector having improved IR detection in the presence of EMI by utilizing previously unused portions of a printed circuit board (PCB) design. It is a further objective to reduce EMI susceptibility of an IR detector by modifying the PCB without changing the type or general layout of circuit elements. It is a further objective to add additional circuit elements providing EMI protection.

Embodiments of the present invention provide an EMI filtering detector. Briefly described, the present invention is directed to a circuit for detecting electromagnetic radiation, including at least one sensor element connected to convert electromagnetic radiation which strikes at least one sensor element into an electric signal, a field effect transistor connected to receive the electric signal from the at least one sensor element, the field effect transistor having a gate terminal, a drain terminal, and a source terminal from which an output signal of the circuit is output, a printed circuit board including at least one low inductance low resistance area selected from the group consisting of a drain terminal trace, a source terminal trace, and a ground connector pad, a first source-ground capacitor connected between the source terminal and ground, a drain-ground capacitor connected between the drain terminal and ground, a gate resistor connected in parallel with the at least one sensor element or a resistor included in the at least one sensor element, and an inductor and resistor connected to the drain terminal through which a supply voltage is supplied to the field effect transistor.

A second aspect of the present invention is directed to a method for manufacturing a detector for sensing electromagnetic radiation including a printed circuit board configured to electrically connect at least one pyroelectric sensor element connected to convert electromagnetic radiation which strikes at least one sensor element into an electric signal, an re-channel junction field effect transistor connected to receive the electric signal from the at least one sensor element, the field effect transistor having a gate terminal, a source terminal from which an output signal of the circuit is output, and the field effect transistor having a drain terminal, the method including the step of forming at least one low inductance low resistance area on the printed circuit board.

Briefly described, in architecture, a third aspect of the present invention is directed to a circuit for detecting electromagnetic radiation, having at least one pyroelectric sensor element connected to convert electromagnetic radiation which strikes at least one sensor element into an electric signal, an n-channel junction field effect transistor connected to receive the electric signal from the at least one sensor element, the field effect transistor having a gate terminal, a source terminal from which an output signal of the circuit is output, and the field effect transistor having a drain terminal, a source-ground capacitor connected between the source terminal and ground, a drain-ground capacitor connected between the drain terminal and ground, a gate resistor connected in parallel to the at least one sensor element or a resistor included in the at least one sensor element, and an inductor and resistor connected to the drain terminal of the field effect transistor through which a supply voltage is supplied to the field effect transistor.

Other systems, methods and features of the present invention will be or become apparent to one having ordinary skill in the art upon examining the following drawings and detailed description. It is intended that all such additional systems, methods, and features be included in this description, be within the scope of the present invention and protected by the accompanying claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principals of the invention.

FIG. 1 is a circuit diagram of a first prior art detector.

FIG. 2 is a circuit diagram of a second prior art detector.

FIG. 3 is a diagram of a prior art printed circuit board.

FIG. 4 is a circuit diagram of an exemplary embodiment of a detector.

FIG. 5 is a diagram of an exemplary embodiment of a printed circuit board and mounted electrical components.

FIG. 6 is a diagram of an exemplary embodiment of a printed circuit board sans electrical components.

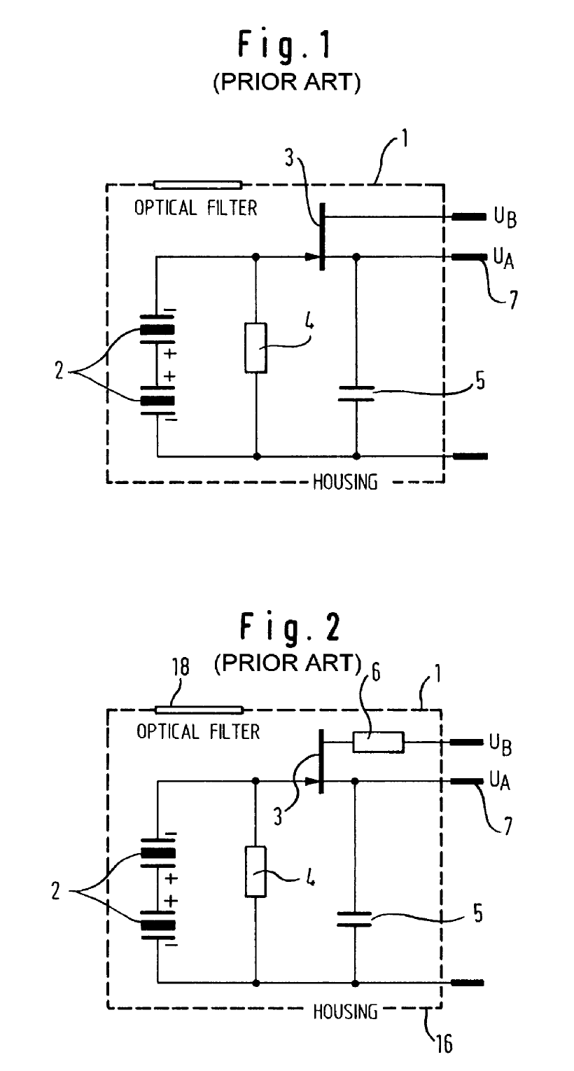

### DETAILED DESCRIPTION

Reference will now be made in detail to embodiments of the present invention, examples of which are illustrated in the accompanying drawings. Wherever possible, the same reference numbers are used in the drawings and the description to refer to the same or like parts.

A radiation detector may include a circular printed circuit board mounted inside a cylindrical housing (or “can”) having a radiation filter or lens at the top and a flat back plate on the bottom. The PCB may be mounted to the housing bottom, for example, with epoxy, and have a minimum number of three electrically connecting pins passing through the bottom, for example, a source pin, a drain pin, and a ground pin.

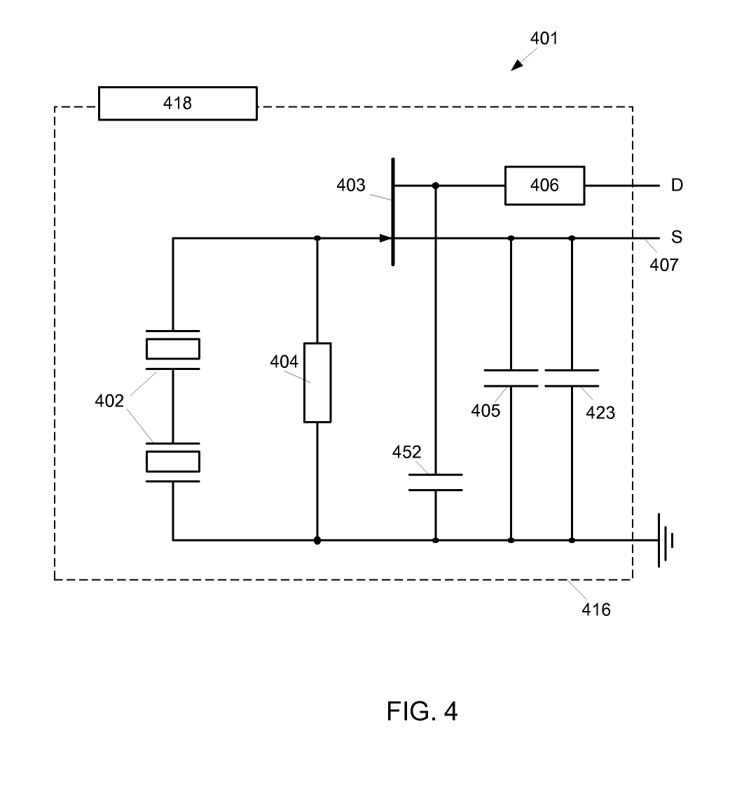

A circuit diagram 401 for a first exemplary embodiment of a radiation detector is shown in FIG. 4. A sensor element 402 which operates capacitively serves to sense electromagnetic radiation, for example, infrared radiation (IR). The sensor element 402 may include, for example, pyroelectric cells. It should be noted that while two sensor elements 402 are depicted in FIG. 4, there is no objection to having 1, 3, 4, or more sensor elements 402 in the circuit 401. The sensor element 402 produces charges corresponding to a change in the intensity of the infrared radiation striking it, and stores these charges capacitively. One terminal of the sensor element 402 is connected to a fixed reference potential, such as ground. The other terminal of the sensor element 402 supplies a voltage as an output signal. Since the sensor element 402 output has an extremely high impedance, an impedance converter is connected to the sensor element 402 output so, for example, an evaluation circuit connected for utilizing the sensor output sees a sufficiently low equivalent resistance for the circuit 401. The impedance converter may be a field-effect transistor (FET) 403. One terminal of the FET 403 is connected to a supply voltage U_{B} while the other terminal of the FET 403 supplies the output signal U_{A} for further processing. In a circuit using an n-channel junction gate FET 403, the sensor element 402 is connected between ground and the gate of the FET 403, the drain is connected to the supply voltage U_{B} and the source is connected to supply the output signal U_{A}.

A first source-ground capacitor 405 is connected between the signal output 407 and ground. The first source-ground capacitor 405 functions as a low pass filter which short circuits the high output frequencies so that these high frequencies are attenuated at the output of the circuit. A second source-ground capacitor 423 is similarly connected between the signal output 407 and ground. The second source-ground capacitor 423 is generally of a smaller capacitance value than the first source-ground capacitor 405, and may therefore filter a higher portion of the EMI frequency range.

Two sensor elements 402 for sensing infrared radiation may be connected in series to one another in antipolar fashion. A discharge resistor 404 of a high impedance is connected in parallel with the series circuit of the sensor elements 402 so that charges produced in response to infrared radiation striking the sensor elements 402 can be discharged over time. Upon the incidence of infrared radiation onto the sensor elements 402, the sensor elements 402 produce charges that cause a voltage at the terminals of the parallel circuit according to the formula U=Q/C. If the infrared radiation which is a irradiating the sensor elements 402 disappears the charge that has arisen in the sensor elements 402 is discharged through the resistor 404. The voltage signal at the terminals of the parallel circuit thus disappears over time. One terminal of the parallel circuit is connected to the gate of the FET 403 which serves as an impedance converter for the sensor elements 402. A first power terminal, the source, for example, of the field effect transistor (FET) 403 supplies an output signal U_{A}.

To reduce sensitivity to radio frequency disturbances, an impedance 406 which is either a purely ohmic impedance or an ohmic and inductive impedance or a purely inductive impedance is connected between the second power terminal, the drain, for example, of the FET 403 and the supply voltage U_{B}. Stray radio frequency voltages which arise in the circuit are coupled from the drain to the gate of the FET 403 via the drain-gate coupling capacitance of the FET 403. The voltage produced at the gate of the FET 403 across the high impedance resistor 404 by the sensor elements 402 is transmitted to the output U_{A} for use in subsequent processing, for example, external processing. The additional drain impedance 406 causes the stray radio frequency voltage signals to be divided between the drain impedance 406 and the drain capacitance 452 working as a low pass filter, The remaining radio frequency voltage across the capacitance 452 is divided among the drain-gate coupling capacitance and the capacitance of the sensor elements 402. Since the capacitive reactances of the FET 403 and the capacitance 452 are small in comparison to the drain impedance 406, some of the stray radio frequency voltages are suppressed at the additional drain impedance 406.

The drain impedance 406 can have an ohmic resistance, an inductance, or a combination of the two. If necessary, the stray radio frequency voltage signals are divided between the inductive reactance, the drain-gate coupling capacitance and the capacitance of the sensor elements 402. Since the inductive reactance increases with frequency, the radio frequency suppression is improved at higher frequencies even more in comparison to a purely ohmic drain resistance element.

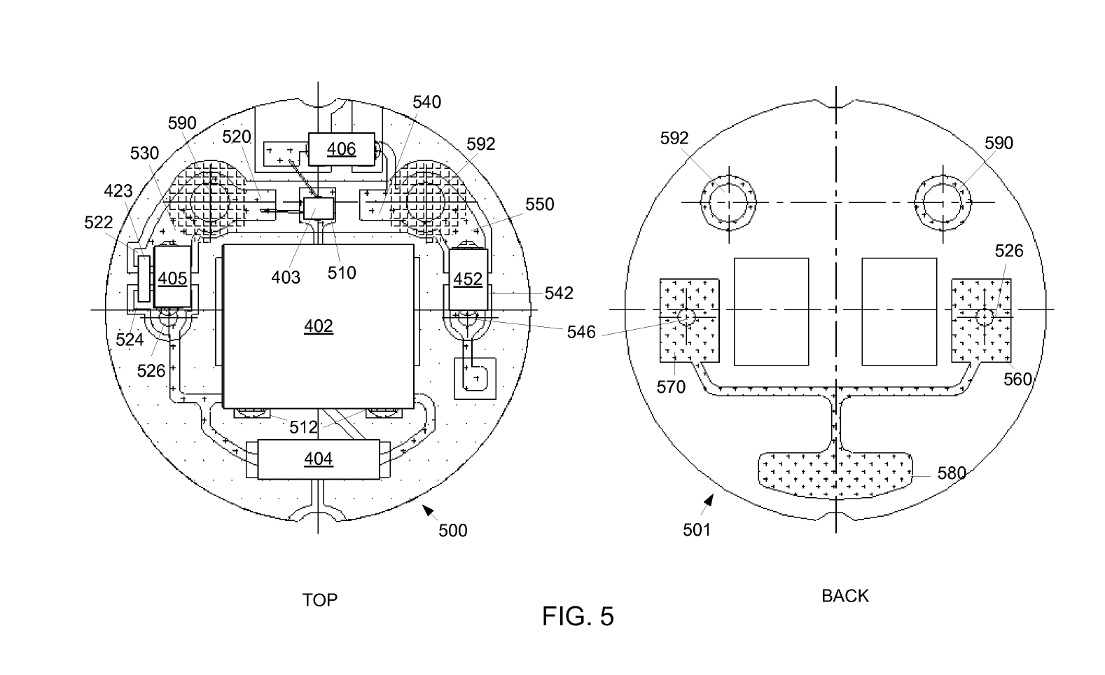

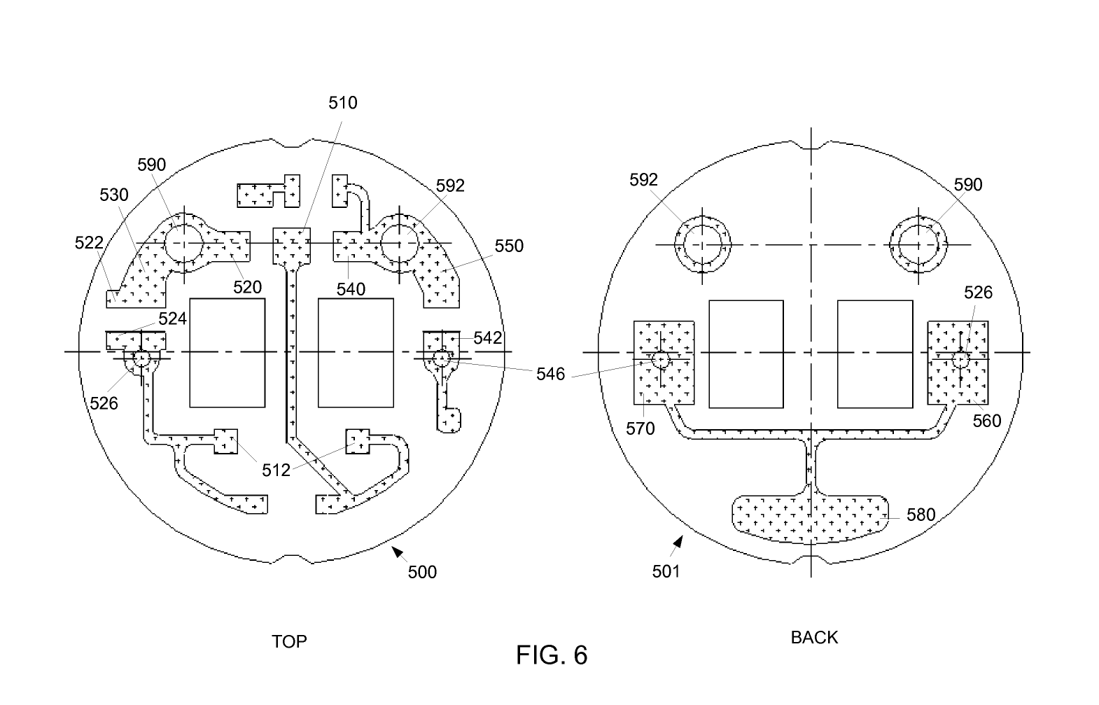

FIG. 5 shows an exemplary printed circuit board (PCB) under the first embodiment, as populated according to the circuit shown in FIG. 4, while FIG. 6 shows the PCB unpopulated for clarity. The circuit components are generally mounted to the PCB top 500, while traces connecting the housing (not shown) to ground are formed on the PCB back 501. An FET 403 is mounted on the FET gate pad 510, which also serves as the electrical connector to the FET 403 gate. One or more pyroelectric elements 402 are connected to sensor connector pads 512. The pyroelectric elements may be mounted on the these pads or, for example, a daughterboard that is in turn mounted to the PCB.

In order to minimize susceptibility to EMI, the inductance and resistance of the PCB traces should be as low as possible. Excess resistance or inductance in certain locations on the PCB reduces the effectiveness of the EMI filtering. In particular, to produce desirable EMI filtering characteristics, a low resistance and inductance path to ground for all the alternating current (AC) components in the detector circuit is preferred. For example, additional resistance or AC impedance (inductance in this case) across capacitors connected to the FET drain and/or source may result in increased susceptibility to detector malfunction due to EMI, particularly in higher frequency ranges. Examples of capacitors connected to the FET drain and/or source include the first source-ground capacitor 405 and/or the second source-ground capacitor 423.

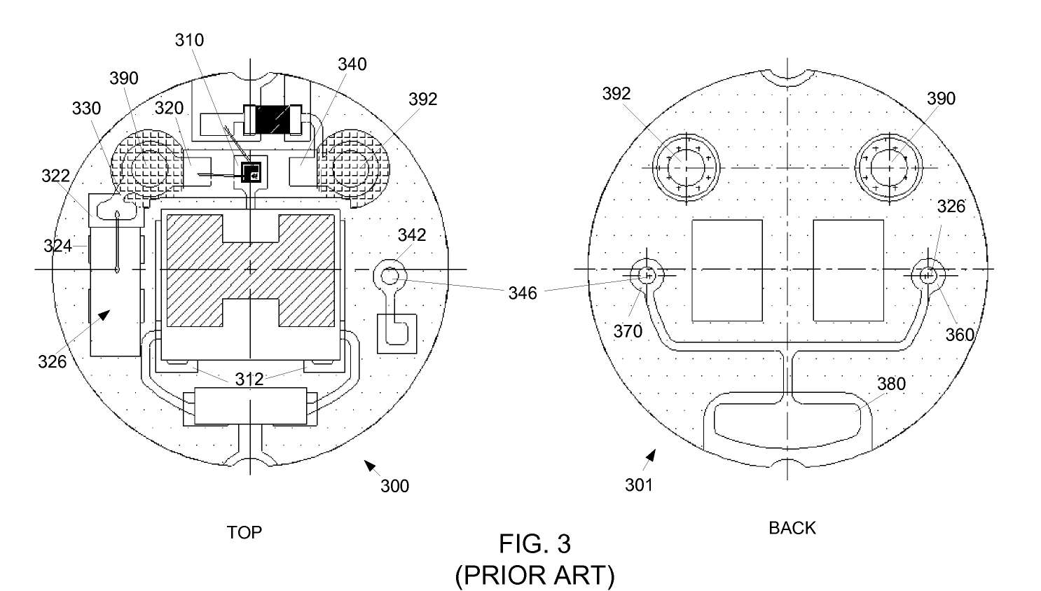

The design of the PCB 500, 501 facilitates lower inductance and resistance by including one or more low inductance low resistance (LILR) areas. The LILR areas generally include an enlarged area trace portion or connection pad on the PCB, where the dimensions of the enlarged trace portion are substantially larger the standard dimensions of a trace portion and/or connection pad for electrical components. A LILR trace is preferably short and wide in comparison with a standard trace. A LILR connection pad may be both longer and wider than a standard connection pad. For example, the dimensions of the LILR area is generally at least two to three times the area of a standard connection pad. However, there is no objection to an LILR area that is as small as, for example, half again the area of a standard connection pad or trace, or an LILR area as large as three or more times the area of a standard connection pad or trace. An example of a detector having standard size connection pads and traces includes the Excelitas LHI 968 IR detector shown in FIG. 3. In contrast, LILR areas under the first embodiment shown in FIG. 5 may include, for example, a drain-capacitor LILR trace 550, a source-capacitor LILR trace 530, a source LILR area ground pad 560, and a drain LILR area ground pad 570. Of course, there is no objection to additional LILR areas on the PCB 500, 501,

An FET source pad 520 is the PCB top 500 electrical connector to the FET 403 source. The source-capacitor LILR trace 530 connects the FET 403 source to a source-ground capacitor source pad 522. The first source-ground capacitor 405 is connected across the source-ground capacitor source pad 522 and a source-ground capacitor ground pad 524. Similarly, the second source-ground capacitor 423 is also connected across the source-ground capacitor source pad 522 and the source-ground capacitor ground pad 524. The source-ground capacitor ground pad 524 on the PCB top 500 is electrically connected to a source back ground pad 560 on the PCB back 501 by a source-ground via 526.

The drain-capacitor LILR trace 550 electrically connects the drain of the FET 403 to one or more circuit elements, for example, the drain-ground capacitor 452 and the drain resistor 406. The source-capacitor LILR trace 530 electrically connects the source of the FET 403 to one or more circuit elements, for example, the first source-ground capacitor 405 and/or the second source-ground capacitor 423.

The increased connection area between electrical components and the LILR areas reduces the resistance in comparison with the resistance of an electrical connection between similar electrical component and standard connection pads. The size and placement of LILR areas reduce parasitic capacitive and/or inductive effects caused by current flow across tracks on the PCB. PCB AC impedance or inductance may be influenced by the location of the LILR areas on the PCB. For example, such capacitance and/or AC impedance or inductance may be reduced by locating a LILR trace on the PCB top 500 in close proximity to, while avoiding overlapping with, a LILR ground pad on the PCB back 501, as overlapping LILR areas may contribute unwanted capacitance.

The source-capacitor LILR trace 530 on the PCB top 500 may electrically connect the FET 403 source with the first source-ground capacitor 405 and/or the second source-ground capacitor 423 spanning the source-ground capacitor source pad 522 and the source-ground capacitor ground pad 524 on the PCB top 500. The source-capacitor LILR trace 530 on the PCB top 500 preferably does not overlap the source LILR ground pad 560 on the PCB back 501, where the source-ground capacitor ground pad 524 on the PCB top 500 is electrically connected to the source LILR ground pad 560 on the PCB back 501 with a source-ground via 526. Similarly, the drain-capacitor LILR trace 550 may electrically connect the FET 403 drain with the drain-ground capacitor 452 spanning the drain-ground capacitor drain pad 550 and the drain-ground capacitor ground pad 542. The drain-capacitor LIRL trace 550 on the PCB top 500 preferably does not overlap the drain LILR ground pad 570 on the PCB back 501, where the drain-ground capacitor ground pad 542 on the PCB top 500 is electrically connected to the drain LILR ground pad 570 on the PCB back 501 with a drain-ground via 546.

The PCB 500, 501 includes a source pin through-hole 590 passing substantially through the source-capacitor LILR trace 530, and a drain pin through-hole 592 passing substantially through the drain-capacitor LILR trace 550. A source pin (not shown) passes through the source pin through-hole 590 in the PCB 500, 501, and electrically connects to the source-capacitor LILR trace 530. A drain pin (not shown) passes through the drain pin through-hole 592 in the PCB 500, 501, and electrically connects to the drain-capacitor LILR trace 550.

While the first embodiment of the radiation detector includes the first source-ground capacitor 405 and the second source-ground capacitor 423, a second exemplary embodiment of a radiation detector similarly includes the first source-ground capacitor 405 but omits second source-ground capacitor 423.

The LILR areas are advantageous over prior art PCBs in that they provide increased resistance to EMI without adding components to the prior art circuit, or materially changing the footprint from the prior art PCB. In particular, the second source-ground capacitor 423 and the drain-ground capacitor 452 of the first embodiment may also be accommodated in a PCB having the same footprint as the prior art PCB. This allows the improved detector device to serve as a direct replacement to the prior art without modifications to existing designs and without excessive additional cost. A person having ordinary skill in the art will recognize that judicious use of LILR areas may reduce susceptibility of the detector to EMI, particularly in the higher frequency ranges, for example, but not limited to a range of 1 GHz to 3 GHz.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit for detecting electromagnetic radiation, comprising:
at least one sensor element connected to convert electromagnetic radiation which strikes at least one sensor element into an electric signal;
a field effect transistor connected to receive said electric signal from said at least one sensor element, said field effect transistor having a gate terminal, a drain terminal, and a source terminal from which an output signal of said circuit is output;
a printed circuit board comprising at least one low inductance low resistance area selected from the group consisting of a drain terminal trace, a source terminal trace, and a ground connector pad;
a first source-ground capacitor connected between said source terminal and ground;
a drain-ground capacitor connected between said drain terminal and ground;
a gate resistor connected in parallel with said at least one sensor element or a resistor included in said at least one sensor element; and
an inductor and resistor connected to said drain terminal through which a supply voltage is supplied to said field effect transistor.

2. The circuit of claim 1, wherein said printed circuit board comprises a first side and a second side, and said field effect transistor is disposed upon said first side.

3. The circuit of claim 2, wherein said ground connector pad is disposed upon said second side and connected to a first side ground connector trace through a via.

4. The circuit of claim 3, wherein said drain terminal trace is disposed upon said first side.

5. The circuit of claim 3, wherein said source terminal trace is disposed upon said first side.

6. The circuit of claim 1, wherein said at least one sensor element is connected between said gate of said field effect transistor and ground.

7. The circuit of claim 1, further comprising a second source-ground capacitor connected between said source terminal and ground, wherein said second source-ground capacitor has a different capacitance value from said first source-ground capacitor.

8. The circuit of claim 1, wherein said at least one sensor element detects infrared radiation.

9. The circuit of claim 8, wherein said at least one sensor element is a pyroelectric cell.

10. The circuit of claim 9, wherein said at least one sensor element is a first sensor element and further comprising a second sensor element which is a pyroelectric cell, said pyroelectric cells being connected in antipolar fashion.

11. The circuit of claim 1, further comprising a housing enclosing said at least one sensor element and said field effect transistor and said impedance.

12. The circuit of claim 1, wherein said field effect transistor is connected as an impedance converter.

13. The circuit of claim 1, wherein said impedance further includes an inductance.

14. The circuit of claim 10, wherein said two pyro electric cells are connected serially.

15. The circuit of in claim 10, wherein said two pyroelectric cells are connected in parallel to one another.

16. A method for manufacturing a detector for sensing electromagnetic radiation comprising a printed circuit board configured to electrically connect at least one pyroelectric sensor element connected to convert electromagnetic radiation which strikes at least one sensor element into an electric signal, an n-channel junction field effect transistor connected to receive said electric signal from said at least one sensor element, said field effect transistor having a gate terminal, a source terminal from which an output signal of said circuit is output, and said field effect transistor having a drain terminal, said method comprising the step of:
forming at least one low inductance low resistance area on said printed circuit board.

17. The method of claim 16, wherein said printed circuit board comprises a first side and a second side, and said printed circuit board is configured to mount said field effect transistor on said first side.

18. The method of claim 17, wherein said at least one low inductance low resistance area is selected from the group consisting of a drain terminal trace, a source terminal trace, and a ground connector pad.

19. The circuit of claim 18, further comprising the steps of:
positioning said ground connector pad upon said second side; and
positioning drain terminal trace on said first side.

20. The circuit of claim 18, further comprising the steps of:
positioning said ground connector pad upon said second side; and
positioning source terminal trace on said first side.

21. A circuit for detecting electromagnetic radiation, comprising:
at least one pyroelectric sensor element connected to convert electromagnetic radiation which strikes at least one sensor element into an electric signal;
an n-channel junction field effect transistor connected to receive said electric signal from said at least one sensor element, said field effect transistor having a gate terminal, a source terminal from which an output signal of said circuit is output, and said field effect transistor having a drain terminal;
a source-ground capacitor connected between said source terminal and ground;
a drain-ground capacitor connected between said drain terminal and ground;
a gate resistor connected in parallel to said at least one sensor element or a resistor included in said at least one sensor element; and
an inductor and resistor connected to said drain terminal of said field effect transistor through which a supply voltage is supplied to said field effect transistor.
